(19) United States
(12) Patent Application Publication
(10) Pub. No.: US 2026/0073103 A1
(43) Pub. Date: Mar. 12, 2026

(54) DESIGN METHOD, PROGRAM, AND DESIGN SYSTEM

(71) Applicant: Panasonic Intellectual Property Management Co., Ltd., Osaka (JP)

(72) Inventor: Fei LIU, Osaka (JP)

(21) Appl. No.: 19/103,920

(22) PCT Filed: Jun. 15, 2023
(86) PCT No.: PCT/JP2023/022249

§ 371 Date: Feb. 14, 2025

(30) Foreign Application Priority Data
Aug. 29, 2022 (JP) 2022-136219

(51) Int. Cl. G06F 30/28; F24F 11/46

(52) U.S. Cl. CPC G06F 30/28; F24F 11/46

(57) ABSTRACT

A selecting step includes obtaining, based on multiple sets, each including an air conditioning energy parameter and a comfort parameter, which have been obtained with respect to multiple samples, respectively, a plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition.

### TECHNICAL FIELD

The present disclosure generally relates to a design method, a program, and a design system. More particularly, the present disclosure relates to a design method, program, and design system for designing a plurality of device parameters concerning an arrangement condition and an operating condition for air conditioning equipment.

### BACKGROUND ART

As an exemplary known system for designing an operating condition for air conditioning equipment, a comfort value management system disclosed in Patent Literature 1 may be cited. The comfort value management system includes an arithmetic processing means. The arithmetic processing means calculates a comfort value at each of a plurality of indoor points by a predetermined arithmetic equation using measured values provided by measuring instruments provided at those indoor points and a preset element value. In addition, the arithmetic processing means also obtains an adjustment value for an air conditioning temperature which is required to change this comfort value into a preset target comfort value and calculates an energy reduction rate corresponding to the adjustment value using a preset energy reduction rate per temperature.

### CITATION LIST

### Patent Literature

Patent Literature 1: JP 2006-162093 A

### SUMMARY OF INVENTION

An object of the present disclosure is to provide a design method, a program, and a design system, all of which contribute to selecting an arrangement condition and an operating condition that ensure both comfortableness and energy saving.

A design method according to an aspect of the present disclosure is a method for designing a plurality of device parameters concerning an arrangement condition and an operating condition for air conditioning equipment. The design method includes an acquisition step, a sampling step, and a set calculating step. The acquisition step includes acquiring information about respective settable ranges of the plurality of device parameters. The plurality of device parameters includes an air volume, an outlet temperature, an installation position, and an air direction of the air conditioning equipment. The sampling step includes determining multiple samples, each being a set of the plurality of device parameters falling within the settable ranges. The set calculating step includes calculating multiple sets, each including an air conditioning energy parameter and a comfort parameter, by performing a simulation step, a first calculating step, a second calculating step, and a third calculating step on every one of the multiple samples. The simulation step includes carrying out a simulation of a thermal fluid distribution in a space of interest by using one sample, selected from the multiple samples, as an input condition. The space of interest forms at least part of a space to be air-conditioned by the air conditioning equipment. The first calculating step includes calculating the air conditioning energy parameter with respect to the one sample. The air conditioning energy parameter is calculated by multiplying an absolute value of a difference between a target temperature of the space of interest and the outlet temperature by the air volume. The second calculating step includes calculating, based on a result of the simulation, a distribution of a predicted mean vote in the space of interest. The third calculating step includes calculating the comfort parameter. The comfort parameter is calculated by dividing a volume of a part of the space of interest where the predicted mean vote has a value falling within a predetermined range by an entire volume of the space of interest. The design method further includes a selecting step. The selecting step includes obtaining, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition.

A program according to another aspect of the present disclosure is designed to cause one or more processors of a computer system to perform the design method described above.

A design system according to still another aspect of the present disclosure is configured to design a plurality of device parameters concerning an arrangement condition and an operating condition for air conditioning equipment. The design system includes an acquirer, a sampler, a simulator, a first calculator, a second calculator, and a third calculator. The acquirer acquires information about respective settable ranges of the plurality of device parameters including an air volume, an outlet temperature, an installation position, and an air direction of the air conditioning equipment. The sampler determines multiple samples, each being a set of the plurality of device parameters falling within the settable ranges. The simulator performs a simulation step including carrying out a simulation of a thermal fluid distribution in a space of interest by using one sample, selected from the multiple samples, as an input condition. The space of interest forms at least part of a space to be air-conditioned by the air conditioning equipment. The first calculator performs a first calculating step including calculating the air conditioning energy parameter with respect to the one sample. The air conditioning energy parameter is calculated by multiplying an absolute value of a difference between a target temperature of the space of interest and the outlet temperature by the air volume. The second calculator performs a second calculating step including calculating, based on a result of the simulation, a distribution of a predicted mean vote in the space of interest. The third calculator performs a third calculating step including calculating the comfort parameter. The comfort parameter is calculated by dividing a volume of a part of the space of interest where the predicted mean vote has a value falling within a predetermined range by an entire volume of the space of interest. The simulator, the first calculator, the second calculator, and the third calculator respectively perform the simulation step, the first calculating step, the second calculating step, and the third calculating step on every one of the multiple samples, thereby calculating multiple sets, each including the air conditioning energy parameter and the comfort parameter. The design system further includes a selector and a result outputter. The selector obtains, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition. The result outputter outputs the plurality of device parameters obtained by the selector.

### BRIEF DESCRIPTION OF DRAWINGS

FIG. 1 is a block diagram of a design system according to an exemplary embodiment;

FIG. 2 illustrates processing to be performed by the design system; and

FIG. 3 is a flowchart showing an exemplary procedure of operation of the design system.

### DESCRIPTION OF EMBODIMENTS

### Embodiment

A design method, a program, and a design system 1 according to an exemplary embodiment will be described with reference to the accompanying drawings. Note that the embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

### (1) Overview

The design system 1 is a system for designing a plurality of device parameters concerning an arrangement condition and an operating condition for air conditioning equipment. The design system 1 may be used, for example, before the operations of installing the air conditioning equipment in a facility are performed, to obtain a plurality of device parameters that satisfy a predetermined condition.

More specifically, the design system 1 obtains, using a predicted mean vote (PMV) as an index, a plurality of device parameters that would ensure comfortableness for a given space. In addition, the design system 1 also obtains, using an air conditioning energy parameter (to be described later) as another index, a plurality of device parameters that would contribute to energy saving.

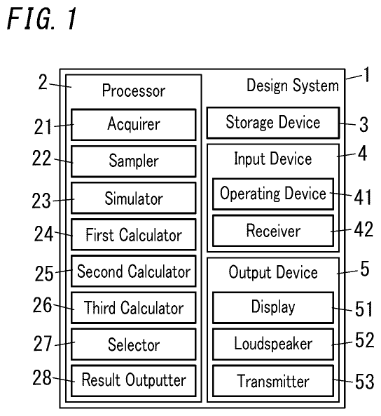

A design system 1 according to this embodiment is configured to design a plurality of device parameters concerning an arrangement condition and an operating condition for air conditioning equipment. As shown in FIG. 1, the design system 1 includes an acquirer 21, a sampler 22, a simulator 23, a first calculator 24, a second calculator 25, and a third calculator 26. The acquirer 21 acquires information about respective settable ranges of the plurality of device parameters including an air volume, an outlet temperature, an installation position, and an air direction of the air conditioning equipment. The installation position is a device parameter concerning the arrangement condition for the air conditioning equipment. The air volume, the outlet temperature, and the air direction are device parameters concerning the operating condition for the air conditioning equipment.

The sampler 22 determines multiple samples, each being a set of the plurality of device parameters falling within the settable ranges. The simulator 23 performs a simulation step including carrying out a simulation of a thermal fluid distribution in a space of interest by using one sample, selected from the multiple samples, as an input condition. The space of interest forms at least part of a space to be air-conditioned by the air conditioning equipment. The first calculator 24 performs a first calculating step including calculating the air conditioning energy parameter with respect to the one sample. The air conditioning energy parameter is calculated by multiplying an absolute value of a difference between a target temperature of the space of interest and the outlet temperature by the air volume. The second calculator 25 performs a second calculating step including calculating, based on a result of the simulation, a distribution of a predicted mean vote (PMV) in the space of interest. The third calculator 26 performs a third calculating step including calculating the comfort parameter. The comfort parameter is calculated by dividing a volume of a part of the space of interest where the predicted mean vote (PMV) has a value falling within a predetermined range by an entire volume of the space of interest. The simulator 23, the first calculator 24, the second calculator 25, and the third calculator 26 respectively perform the simulation step, the first calculating step, the second calculating step, and the third calculating step on every one of the multiple samples, thereby calculating multiple sets, each including an air conditioning energy parameter and a comfort parameter. The design system 1 further includes a selector 27 and a result outputter 28. The selector 27 obtains, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition. The result outputter 28 outputs the plurality of device parameters obtained by the selector 27.

This embodiment enables selecting (a plurality of device parameters concerning) an arrangement condition and an operating condition that ensure both comfortableness based on the PMV and energy saving alike. For example, the user may choose air conditioning equipment with such specifications that would achieve the plurality of device parameters selected by the design system 1. Then, the user may adjust the installation position of the air conditioning equipment and set the air volume, outlet temperature, air direction, and other parameters of the air conditioning equipment in accordance with the plurality of device parameters selected. This enables ensuring comfortableness and energy saving for a real space.

Alternatively, the functions of the design system 1 may also be implemented as a design method. A design method according to this embodiment is a method for designing a plurality of device parameters concerning an arrangement condition and an operating condition for air conditioning equipment. The design method includes an acquisition step, a sampling step, and a set calculating step. The acquisition step includes acquiring information about respective settable ranges of the plurality of device parameters. The plurality of device parameters includes an air volume, an outlet temperature, an installation position, and an air direction of the air conditioning equipment. The sampling step includes determining multiple samples, each being a set of the plurality of device parameters falling within the settable ranges. The set calculating step includes calculating multiple sets, each including an air conditioning energy parameter and a comfort parameter, by performing a simulation step, a first calculating step, a second calculating step, and a third calculating step on every one of the multiple samples. The simulation step includes carrying out a simulation of a thermal fluid distribution in a space of interest by using one sample, selected from the multiple samples, as an input condition. The space of interest forms at least part of a space to be air-conditioned by the air conditioning equipment. The first calculating step includes calculating the air conditioning energy parameter with respect to the one sample. The air conditioning energy parameter is calculated by multiplying an absolute value of a difference between a target temperature of the space of interest and the outlet temperature by the air volume. The second calculating step includes calculating, based on a result of the simulation, a distribution of a predicted mean vote (PMV) in the space of interest. The third calculating step includes calculating the comfort parameter. The comfort parameter is calculated by dividing a volume of a part of the space of interest where the predicted mean vote (PMV) has a value falling within a predetermined range by an entire volume of the space of interest. The design method further includes a selecting step. The selecting step includes obtaining, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition.

Still alternatively, the design method may also be implemented as a program. A program according to this embodiment is designed to cause one or more processors of a computer system to perform the design method described above. The program may be stored in a non-transitory storage medium, which is readable for the computer system.

### (2) Details

The design system 1 according to this embodiment will be described in further detail.

The space to be air-conditioned by the air conditioning equipment may be, for example, an indoor room of a facility. Examples of the facility in which the air conditioning equipment is installed include dwelling houses, office buildings, factories, shopping malls, libraries, art museums, museums, amusement facilities, airports, railway stations, hotels, nursing care facilities, and hospitals. Alternatively, the facility may also be a moving vehicle such as a watercraft, a railway train, or an aircraft

In the following description of embodiments, the air conditioning equipment is supposed to be an air conditioner, as an example. More specifically, in the following description of embodiments, the air conditioning equipment is supposed to be a wall-mounted air conditioner.

In this embodiment, the number of the device parameters is seven. The seven device parameters are an air volume, an outlet temperature, X, Y, and Z coordinates of the installation position, air directions in the upward/downward directions, and air directions in the rightward/leftward directions. In this case, the X-, Y-, and Z-axes are perpendicular to each other. The X-axis and the Y-axis are axes parallel to the horizontal plane, and the Z-axis is an axis perpendicular to the horizontal plane.

In this embodiment, the number of the air conditioning equipment, for which the arrangement condition, the operating condition, (and the plurality of device parameters) are designed by the design system 1 is supposed to be one. However, this is only an example and should not be construed as limiting. Alternatively, the design system 1 may also design respective arrangement conditions and respective operating conditions for a plurality of air conditioning equipments. For example, if the number of the air conditioning equipments provided is N and the number of the device parameters to be designed per air conditioning equipment is M, then the number of the device parameters to be designed by the design system 1 is N×M, and one sample will have N×M device parameters. In this embodiment, N=1 and M=7.

As shown in FIG. 1, the design system 1 includes a processor 2, a storage device 3, an input device 4, and an output device 5.

The storage device 3 may be implemented as, for example, a hard disk drive (HDD) or a solid-state drive (SSD). The storage device 3 stores information. The storage device 3 may store, as information required for designing an arrangement condition and an operating condition for the air conditioning equipment, the specifications of the air conditioning equipment, three-dimensional data of the facility, and thermal conductivities of the walls, floor, and ceiling of the facility, for example.

The input device 4 accepts entry of information conveyed from outside of the design system 1. The input device 4 may include, for example, at least one of an operating device 41 or a receiver 42.

The operating device 41 may include, for example, at least one of a button, a key switch, a touchscreen panel, or a touchscreen panel display. The operating device 41 accepts an operating command entered by the user. The user is allowed to enter information required for designing the arrangement condition and operating condition for the air conditioning equipment into the design system 1 or make the design system 1 start designing the arrangement condition and the operating condition by operating the operating device 41. The user may determine, for example, the target temperature of the space of interest, a threshold value to be compared with the comfort parameter, and the settable ranges of the device parameters by operating the operating device 41.

The receiver 42 receives information from another device. The receiver 42 receives information either directly or indirectly via a network or a repeater, for example, by an appropriate communication method which may be either wired communication or wireless communication. For example, the receiver 42 receives information about the specifications of the air conditioning equipment, the three-dimensional data of the facility, and the air temperature of a region where the facility is located.

The output device 5 outputs the information. The output device 5 includes at least one of a display 51, a loudspeaker 52, or a transmitter 53, for example.

The output device 5 displays the information on the display 51. The output device 5 may display, on the display 51, at least one of the arrangement condition or operating condition which has been obtained by the design system 1, for example.

The output device 5 also outputs the information as a sound (including voice) emitted through the loudspeaker 52. The output device 5 may output, through the loudspeaker 52, at least one of the arrangement condition or operating condition which has been obtained by the design system 1, for example.

The transmitter 53 transmits information to another device. The transmitter 53 transmits information either directly or indirectly via a network or a repeater, for example, by an appropriate communication method which may be either wired communication or wireless communication. For example, the transmitter 53 may transmit the arrangement condition and the operating condition which have been obtained by the design system 1, for example.

The processor 2 includes a computer system including one or more processors and a memory. At least some functions of the processor 2 are performed by making the processor of the computer system execute a program stored in the memory of the computer system. The program may be stored in the memory. Alternatively, the program may also be downloaded via a telecommunications line such as the Internet or distributed after having been stored in a non-transitory storage medium such as a memory card.

The processor 2 includes the acquirer 21, the sampler 22, the simulator 23, the first calculator 24, the second calculator 25, the third calculator 26, the selector 27, and the result outputter 28. Note that these constituent elements of the processor 2 just represent respective functions to be performed by the processor 2 and do not necessarily have substantive configurations.

The acquirer 21 acquires information about respective settable ranges of the plurality of device parameters. The information about the settable ranges may be stored in advance in the storage device 3, for example. The acquirer 21 reads out the information about the settable ranges from the storage device 3. Alternatively, the user may enter information about the settable ranges via the operating device 41 of the input device 4 and the acquirer 21 may acquire, from the operating device 41, the information about the settable ranges which has been entered via the operating device 41. Still alternatively, the acquirer 21 may also acquire, from the receiver 42, information about the settable ranges which has been entered into the receiver 42 from another device.

Information about the settable range of the outlet temperature of the air conditioning equipment may include, for example, information about every settable outlet temperature. Specifically, if the outlet temperature may be set at 10° C., 11° C., 12° C., . . . , and 30° C., then the respective values of 10° C., 11° C., 12° C., . . . , and 30° C. correspond to pieces of information about the settable range of the outlet temperature of the air conditioning equipment.

Alternatively, information about the settable range of the outlet temperature of the air conditioning equipment may also include, for example, pieces of information about a minimum value of the outlet temperature, a maximum value of the outlet temperature, and a minimum variation when the outlet temperature is changed between the minimum value and the maximum value.

Information about the settable range of the air volume the air conditioning equipment may include, for example, information about every settable air volume. Alternatively, information about the settable range of the air volume of the air conditioning equipment may also include, for example, pieces of information about a minimum value of the air volume, a maximum value of the air volume, and a minimum variation when the air volume is changed between the minimum value and the maximum value. The minimum value of the air volume may be greater than zero.

Information about the settable range of the installation position of the air conditioning equipment may be obtained, for example, based on three-dimensional data of the facility. Information about the settable range of the installation position of the air conditioning equipment represents the ranges of the respective values that the X, Y, and Z coordinates of the installation position may assume.

The air direction of the air conditioning equipment may be represented by, for example, an angle corresponding to the air direction. Information about the settable range of the air direction in the upward/downward directions of the air conditioning equipment may include, for example, information about an angle when the air direction is most upward, information about an angle when the air direction is most downward, and information about a minimum variation in the angle when the air direction is changed upward and downward. Information about the settable range of the rightward/leftward air directions of the air conditioning equipment may include, for example, information about an angle when the air direction is most leftward, information about an angle when the air direction is most rightward, and information about a minimum variation in the angle when the air direction is changed to the right and to the left.

The sampler 22 determines multiple samples, each being a set of a plurality of (e.g., seven) device parameters falling within their respective settable ranges acquired by the acquirer 21. Specifically, to determine one sample, the sampler 22 sets each of the seven device parameters (namely, the air volume, the outlet temperature, the X, Y, and Z coordinates of the installation position, the upward/downward air directions, and the rightward/leftward air directions) at a single value. A set consisting of the seven device parameters thus determined is one sample.

The processing performed by the sampler 22 corresponds to the sampling step. The sampling step includes determining the multiple samples by design of experiments. As the design of experiments, either the Latin hypercube sampling method or the Monte Carlo method may be adopted, for example. The following Table 1 shows an example of multiple samples determined by the design of experiments:

TABLE 1

| | |
|---|---|
| Sample | Factor column |

| No. | A | B | C | D | E | F | G |
|---|---|---|---|---|---|---|---|
| I | 1 | 1 | 1 | 1 | 1 | 1 | 1 |
| II | 1 | 1 | 1 | 2 | 2 | 2 | 2 |
| III | 1 | 2 | 2 | 1 | 1 | 2 | 2 |
| IV | 1 | 2 | 2 | 2 | 2 | 1 | 1 |
| V | 2 | 1 | 2 | 1 | 2 | 1 | 2 |
| VI | 2 | 1 | 2 | 2 | 1 | 2 | 1 |
| VII | 2 | 2 | 1 | 1 | 2 | 2 | 1 |
| VIII | 2 | 2 | 1 | 2 | 1 | 1 | 2 |

The seven factors A-G agree with the seven device parameters, respectively. That is to say, in this embodiment, the number of factors is seven. Also, in Table 1, the number of times of tests (i.e., the number of samples) is eight and the number of levels is two.

The simulator 23 performs the simulation step. That is to say, the simulator 23 carries out a simulation of a thermal fluid distribution in the space of interest by using one sample, selected from the multiple samples, as an input condition. In this case, the space of interest does not have to be the entire space partitioned by the walls, floor, ceiling, and other building components of the room but may also be only a part of the entire space. For example, the space of interest may be only a region where a person is staying (such as a region surrounding a desk) out of the entire space. That is to say, the space of interest does not have to be a space separated from other spaces.

Note that in this embodiment, the number of the air conditioning equipment, for which (the plurality of device parameters concerning) the arrangement condition and the operating condition are designed by the design system 1, is one, and the simulator 23 carries out a simulation of the thermally fluid distribution formed by the single air conditioning equipment. Nevertheless, if the number of the air conditioning equipments is plural, the simulator 23 carries out a simulation of the thermal fluid distribution formed by the plurality of air conditioning equipments.

The parameters to be referred to for the purpose of simulation are not limited to the sample determined by the sampler 22. Rather, the temperature of the region where the facility is located, the three-dimensional data of the facility, and thermal conductivities of the walls, floor, ceiling, and other building components of the facility may be further referred to. The simulator 23 carries out the simulation based on these parameters.

In addition, the simulator 23 also carries out the simulation on every one of the multiple samples. Thus, the simulator 23 outputs a result of simulation corresponding to each sample. For example, if eight samples, numbered I through VIII, respectively, as shown in Table 1, are determined, then the simulator 23 outputs a result of simulation carried out using the sample with number I as an input condition, a result of simulation carried out using the sample with number II as an input condition, . . . , and a result of simulation carried out using the sample with number VIII as an input condition.

The first calculator 24 calculates an air conditioning energy parameter with respect to one sample. As used herein, the air conditioning energy parameter is calculated by multiplying the absolute value of a difference between a target temperature of the space of interest and the outlet temperature by the air volume. The outlet temperature and the air volume are values included in the one sample. The target temperature may be a value that has been entered into the input device 4, for example.

If the air conditioning energy parameter is W, the air volume is F, the target temperature is Ta, and the outlet temperature is Tb, then the following equation (1) is satisfied:

$$W = F \times \vert Ta - Tb \vert . \qquad ( 1 )$$

In addition, the first calculator 24 calculates the air conditioning energy parameter with respect to every one of the multiple samples. Thus, the first calculator 24 calculates a plurality of air conditioning energy parameters corresponding one to one to the multiple samples. For example, if eight samples, numbered I through VIII, respectively, as shown in Table 1, are determined, then the first calculator 24 calculates a first air conditioning energy parameter based on the outlet temperature and air volume included in the sample with number I, a second air conditioning energy parameter based on the outlet temperature and air volume included in the sample with number II, . . . , and an eighth air conditioning energy parameter based on the outlet temperature and air volume included in the sample with number VIII.

The second calculator 25 calculates the PMV distributions in the space of interest based on the results of the simulations carried out by the simulator 23. In this case, the simulator 23 outputs the results of eight simulations corresponding one to one to the eight samples with numbers I-VIII, respectively. The second calculator 25 calculates eight PMV distributions corresponding one to one to the results of the eight simulations. That is to say, the second calculator 25 calculates one PMV distribution based on the result of one simulation. The PMV distribution may be a two-dimensional distribution or a three-dimensional distribution, whichever is appropriate.

The second calculator 25 calculates the PMV by the PMV calculation equation defined by ISO 7730. Examples of parameters that determine the PMV include the air temperature in the space of interest, the radiation temperature in the space of interest, the average air velocity in the space of interest, the relative humidity in the space of interest, the metabolic rate of a person, and the amount of clothing worn by the person. The second calculator 25 extracts an air temperature at a point of interest, for which the PMV is calculated, from the result of the simulation carried out by the simulator 23. When the PMV is calculated, respective values at a representative point in the space of interest may be used as for the radiation temperature, the average air velocity, and the relative humidity. The radiation temperature may be measured by a sensor installed in the space of interest, for example. Alternatively, the radiation temperature may also be assumed to be equal to the air temperature. The average air velocity and the relative humidity may be measured by sensors installed in the space of interest, may be preset values, or may be obtained by the simulator 23 through simulations. As for the metabolic rate and the amount of clothing of a person, either preset values or the values entered by the user via the operating device 41 may be used, whichever is appropriate.

The third calculator 26 calculates a comfort parameter based on the PMV distribution calculated by the second calculator 25. The comfort parameter is calculated by dividing the volume of a part of the space of interest where the PMV has a value falling within a predetermined range by the entire volume of the space of interest. In this case, the second calculator 25 outputs eight PMV distributions corresponding one to one to eight samples with numbers I-VIII, respectively. The third calculator 26 calculates eight comfort parameters corresponding one to one to the eight PMV distributions. The predetermined range preferably includes zero. For example, the predetermined range may be equal to or greater than −0.5 and equal to or less than 0.5. The predetermined range may be, for example, a preset range or a range entered by the user into the operating device 41, whichever is appropriate.

If the comfort parameter is C, the entire volume of the space of interest is V, and the volume of the part of the space of interest where the PMV has a value falling within the predetermined range is Vp, the following Equation (2) is satisfied:

$$C = Vp / V \qquad ( 2 )$$

A plurality of (e.g., eight) air conditioning energy parameters corresponding one to one to the multiple samples are calculated by the first calculator 24. A plurality of (e.g., eight) comfort parameters corresponding one to one to the multiple samples are calculated by the third calculator 26. That is to say, the design system 1 performs the simulation step, the first calculating step, the second calculating step, and the third calculating step on every one of the multiple samples, thereby calculating multiple (eight) sets, each including the air conditioning energy parameter and the comfort parameter.

The selector 27 performs a selecting step. Specifically, the selector 27 obtains, based on the multiple sets, each including the air conditioning energy parameter and the comfort parameter, the plurality of (e.g., seven) device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition.

For example, the threshold value may be a value equal to or greater than 0.9 and equal to or less than 1.0. The threshold value is preferably a value equal to or greater than 0.9 and equal to or less than 0.91. The threshold value may be, for example, 0.9, 0.901, or 0.902. The threshold value may be, for example, a preset value or a value entered by the user into the operating device 41, whichever is appropriate.

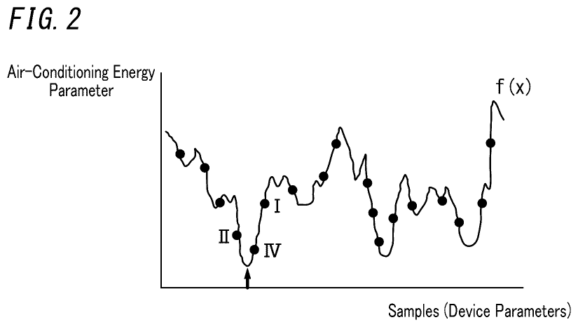

The selecting step includes generating interpolated data by interpolating data between the multiple samples. The selecting step further includes obtaining, based on the interpolated data, the plurality of device parameters that satisfy both the first condition and the second condition. This respect will be described with reference to FIG. 2.

The selecting step may include, for example, deriving an approximate function f(x) for output data based on, for example, N-point input/output data (x1, f(x1)), . . . , and (xN, f(xN)). In this case, the input data x1, . . . , xN are respective samples and the output data f(x1) . . . , f(xN) are respective air conditioning energy parameters. The approximate function f(x) is a function which uses the seven device parameters as variables and x represents the seven device parameters. Note that for the sake of convenience of illustration, x is represented as a single axis (i.e., the axis of abscissas) in FIG. 2. Note that in the foregoing description, the number of samples is supposed to be eight as shown in Table 1. The case shown in FIG. 2 is different from the case described above. In FIG. 2, the number N of samples is greater than eight.

The approximate function f(x) is the interpolated data described above. That is to say, the data between the multiple samples is interpolated as shown in FIG. 2 by making the selector 27 derive the approximate function f(x). For example, an air conditioning energy parameter in a situation where the values of the plurality of device parameters are values between the sample II and the sample IV is represented by the approximate function f(x).

The selector 27 determines, based on the approximate function f(x), that when the values of the plurality of device parameters are values between the sample II and the sample IV, the air conditioning energy parameter becomes minimum (as indicated by the arrow in FIG. 2). In this case, if the comfort parameter derived from the plurality of device parameters (hereinafter referred to as a “a plurality of first device parameters”) is greater than the threshold value, then the plurality of first device parameters satisfy both the first condition and the second condition.

That is to say, the simulator 23 carries out a simulation of the thermal fluid distribution by using the plurality of first device parameters as an input condition, the second calculator 25 calculates a PMV distribution and the third calculator 26 calculates the comfort parameter based on the result of the simulation. If the comfort parameter is greater than the threshold value, the plurality of first device parameters satisfy both the first condition and the second condition. On the other hand, if the comfort parameter is less than the threshold value, then the selector 27 determines, with respect to another plurality of device parameters, whether both the first condition and the second condition are satisfied.

In this manner, the selector 27 obtains a plurality of device parameters that satisfy both the first condition and the second condition. Optionally, to obtain the plurality of device parameters in a situation where the air conditioning energy parameter becomes minimum, the selector 27 may employ an annealing method, the Bayes optimization method, the generic algorithm, or the parameter study.

The result outputter 28 controls the output device 5. This allows the result outputter 28 to output, via the output device 5, the plurality of device parameters obtained by the selector 27.

Optionally, the result outputter 28 may have the plurality of device parameters displayed on the display 51, for example. In that case, the user may set a plurality of device parameters for the air conditioning equipment by reference to the information displayed on the display 51.

Alternatively, the result outputter 28 may have the plurality of device parameters transmitted to the air conditioning equipment via the transmitter 53, for example, thereby setting the air volume, the outlet temperature, and air direction of the air conditioning equipment.

### (3) Exemplary Operation

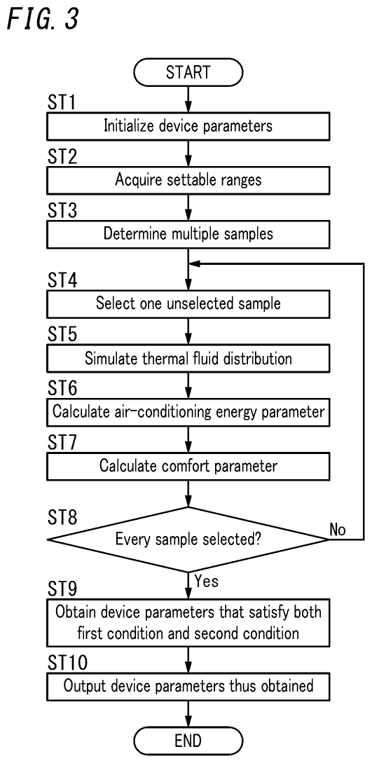

An exemplary procedure of operation of the design system 1 is shown in FIG. 3. Note that the flowchart shown in FIG. 3 is only an exemplary procedure of operation of the design system 1 and should not be construed as limiting. Optionally, the processing steps shown in FIG. 3 may be performed in a different order as appropriate from the illustrated one, some of the processing steps shown in FIG. 3 may be omitted as appropriate, and/or an additional processing step may be performed as needed.

First, the design system 1 initializes the plurality of (e.g., seven) device parameters stored in the storage device 3 (in Step ST1). Next, the acquirer 21 acquires respective settable ranges of the plurality of device parameters (in Step ST2). Furthermore, the sampler 22 determines multiple samples (in Step ST3). Each of the multiple samples is a set of the plurality of device parameters and the respective device parameters of the sample have values falling within the settable ranges acquired by the acquirer 21. The number of the samples is preferably equal to or greater than 20, for example.

Next, the design system 1 selects one sample from the multiple samples determined by the sampler 22 (in Step ST4). In Steps ST5-ST7, the design system 1 performs processing on the sample selected in Step ST4. More specifically, the simulator 23 carries out a simulation of a thermal fluid distribution in the space of interest by using the sample as an input condition (in Step ST5). The first calculator 24 multiplies the absolute value of the difference between the target temperature of the space of interest and the outlet temperature by the air volume, thereby calculating an air conditioning energy parameter (in Step ST6). The outlet temperature and air volume for use to calculate the air conditioning energy parameter are included in the sample. The second calculator 25 calculates a PMV distribution in the space of interest based on the result of the simulation carried out by the simulator 23. The third calculator 26 calculates a comfort parameter based on the PMV distribution (in Step ST7).

In Step ST8 following Steps ST5-ST7, a determination is made whether every one of the multiple samples determined by the sampler 22 has been selected in Step ST4. If there is one or more unselected samples (if the answer is NO in Step ST8), the process returns to Step S4, in which the design system 1 selects one unselected sample and performs Steps ST5-ST7 on the sample thus selected. An air conditioning energy parameter and a comfort parameter corresponding to each sample are obtained by performing the series of Steps ST4-ST7 the same number of times as the number of the samples.

Next, the selector 27 obtains a plurality of device parameters that satisfy both the first condition and the second condition based on multiple sets, each including the air conditioning energy parameter and the comfort parameter (in Step ST9). Finally, the result outputter 28 outputs the plurality of device parameters obtained by the selector 27 (in Step ST10).

### Variations of Embodiment

Next, variations of the exemplary embodiment will be enumerated one after another. Note that the variations to be described below may be adopted in combination as appropriate.

The type of the air conditioning equipment is not limited to an air conditioner. Alternatively, the air conditioning equipment may also be, for example, a heater or a freezing machine, or a combination of either the heater or the freezing machine and an air conditioning duct, a blower, or ventilation equipment.

Some device parameters belonging to the plurality of device parameters may each have a fixed value. For example, if the design system 1 is used for preexistent air conditioning equipment as a target, then the installation position of the air conditioning equipment, belonging to the plurality of device parameters, may have a fixed value. Alternatively, the rightward/leftward air directions, belonging to the plurality of device parameters, for example, may also be fixed.

For example, if the air conditioning equipment is an air conditioner to be embedded on the ceiling, for example, then the plurality of device parameters may include forward/backward air directions instead of the upward/downward air directions. That is to say, the plurality of device parameters may include the forward/backward air directions and the rightward/leftward air directions.

The selector 27 only needs to obtain at least a plurality of device parameters that satisfy both the first condition and the second condition. In addition, the selector 27 may also obtain a plurality of device parameters that satisfy both the first condition and a third condition. That is to say, the selector 27 may obtain two or more arrangement conditions. The selector 27 may also obtain two or more operating conditions. The second condition is a condition that the air conditioning energy parameter be minimized (i.e., be a minimum value) within the range of the plurality of device parameters that satisfy the first condition. The third condition is a condition that the difference between the air conditioning energy parameter and the minimum value be equal to or less than a predetermined value within the range of the plurality of device parameters that satisfy the first condition.

The design system 1 according to the present disclosure or the agent that performs the design method according to the present disclosure includes a computer system. The computer system may include a processor and a memory as principal hardware components thereof. The computer system performs at least some functions of the design system 1 according to the present disclosure or serves as the agent that performs the design method according to the present disclosure by making the processor execute a program stored in the memory of the computer system. The program may be stored in advance in the memory of the computer system.

Alternatively, the program may also be downloaded through a telecommunications line or be distributed after having been recorded in some non-transitory storage medium such as a memory card, an optical disc, or a hard disk drive, any of which is readable for the computer system. The processor of the computer system may be made up of a single or a plurality of electronic circuits including a semiconductor integrated circuit (IC) or a large-scale integrated circuit (LSI). As used herein, the “integrated circuit” such as an IC or an LSI is called by a different name depending on the degree of integration thereof. Examples of the integrated circuits such as an IC or an LSI include integrated circuits called a “system LSI,” a “very-large-scale integrated circuit (VLSI),” and an “ultra-large-scale integrated circuit (ULSI).” Optionally, a field-programmable gate array (FPGA) to be programmed after an LSI has been fabricated or a reconfigurable logic device allowing the connections or circuit sections inside of an LSI to be reconfigured may also be adopted as the processor. Those electronic circuits may be either integrated together on a single chip or distributed on multiple chips, whichever is appropriate. Those multiple chips may be aggregated together in a single device or distributed in multiple devices without limitation. As used herein, the “computer system” includes a microcontroller including one or more processors and one or more memories. Thus, the microcontroller may also be implemented as a single or a plurality of electronic circuits including a semiconductor integrated circuit or a large-scale integrated circuit.

In the embodiment described above, the plurality of functions of the design system 1 are integrated together in a single device. However, this is not an essential configuration for the design system 1. Alternatively, those constituent elements of the design system 1 may be distributed in multiple different devices. Still alternatively, at least some functions of the design system 1 (e.g., some functions of the processor 2) may be implemented as either a server or a cloud computing system as well.

### (Recapitulation)

The exemplary embodiment and its variations described above are specific implementations of the following aspects of the present disclosure.

A design method according to a first aspect is a method for designing a plurality of device parameters concerning an arrangement condition and an operating condition for air conditioning equipment. The design method includes an acquisition step, a sampling step, and a set calculating step. The acquisition step includes acquiring information about respective settable ranges of the plurality of device parameters. The plurality of device parameters includes an air volume, an outlet temperature, an installation position, and an air direction of the air conditioning equipment. The sampling step includes determining multiple samples, each being a set of the plurality of device parameters falling within the settable ranges. The set calculating step includes calculating multiple sets, each including an air conditioning energy parameter and a comfort parameter, by performing a simulation step, a first calculating step, a second calculating step, and a third calculating step on every one of the multiple samples. The simulation step includes carrying out a simulation of a thermal fluid distribution in a space of interest by using one sample, selected from the multiple samples, as an input condition. The space of interest forms at least part of a space to be air-conditioned by the air conditioning equipment. The first calculating step includes calculating the air conditioning energy parameter with respect to the one sample. The air conditioning energy parameter is calculated by multiplying an absolute value of a difference between a target temperature of the space of interest and the outlet temperature by the air volume. The second calculating step includes calculating, based on a result of the simulation, a distribution of a predicted mean vote in the space of interest. The third calculating step includes calculating the comfort parameter. The comfort parameter is calculated by dividing a volume of a part of the space of interest where the predicted mean vote has a value falling within a predetermined range by an entire volume of the space of interest. The design method further includes a selecting step. The selecting step includes obtaining, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition.

This method enables selecting (a plurality of device parameters concerning) an arrangement condition and an operating condition that ensure both comfortableness based on the predicted mean vote and energy saving alike.

In a design method according to a second aspect, which may be implemented in conjunction with the first aspect, the sampling step includes determining the multiple samples by design of experiments.

This method enables shortening, by reducing the number of samples, the time it takes to select the arrangement condition and the operating condition.

In a design method according to a third aspect, which may be implemented in conjunction with the first or second aspect, the predetermined range is equal to or greater than −0.5 and equal to or less than 0.5.

This method enables providing a comfortable space.

In a design method according to a fourth aspect, which may be implemented in conjunction with any one of the first to third aspects, the threshold value is a value equal to or greater than 0.9 and equal to or less than 1.0.

This method enables providing a comfortable space.

In a design method according to a fifth aspect, which may be implemented in conjunction with any one of the first to fourth aspects, the selecting step includes generating interpolated data by interpolating data between the multiple samples. The selecting step further includes obtaining, based on the interpolated data, the plurality of device parameters that satisfy both the first condition and the second condition.

This method enables, in a situation where the comfort parameter is set at a value greater than a threshold value and the air conditioning energy parameter is minimized, providing a smaller air conditioning energy parameter than selecting a plurality of device parameters from multiple samples.

Note that the features according to the second to fifth aspects are not essential features for the design method but may be omitted as appropriate.

A program according to a sixth aspect is designed to cause one or more processors of a computer system to perform the design method according to any one of the first to fifth aspects.

This program enables selecting (a plurality of device parameters concerning) an arrangement condition and an operating condition that ensure both comfortableness based on the predicted mean vote and energy saving alike.

A design system (1) according to a seventh aspect is configured to design a plurality of device parameters concerning an arrangement condition and an operating condition for air conditioning equipment. The design system (1) includes an acquirer (21), a sampler (22), a simulator (23), a first calculator (24), a second calculator (25), and a third calculator (26). The acquirer (21) acquires information about respective settable ranges of the plurality of device parameters. The plurality of device parameters includes an air volume, an outlet temperature, an installation position, and an air direction of the air conditioning equipment. The sampler (22) determines multiple samples, each being a set of the plurality of device parameters falling within the settable ranges. The simulator (23) performs a simulation step including carrying out a simulation of a thermal fluid distribution in a space of interest by using one sample, selected from the multiple samples, as an input condition. The space of interest forms at least part of a space to be air-conditioned by the air conditioning equipment. The first calculator (24) performs a first calculating step including calculating the air conditioning energy parameter with respect to the one sample. The air conditioning energy parameter is calculated by multiplying an absolute value of a difference between a target temperature of the space of interest and the outlet temperature by the air volume. The second calculator (25) performs a second calculating step including calculating, based on a result of the simulation, a distribution of a predicted mean vote in the space of interest. The third calculator (26) performs a third calculating step including calculating the comfort parameter. The comfort parameter is calculated by dividing a volume of a part of the space of interest where the predicted mean vote has a value falling within a predetermined range by an entire volume of the space of interest. The simulator (23), the first calculator (24), the second calculator (25), and the third calculator (26) respectively perform the simulation step, the first calculating step, the second calculating step, and the third calculating step on every one of the multiple samples, thereby calculating multiple sets, each including the air conditioning energy parameter and the comfort parameter. The design system (1) further includes a selector (27) and a result outputter (28). The selector (27) obtains, based on the multiple sets, each including the air conditioning energy parameter and the comfort parameter, which have been obtained with respect to the multiple samples, respectively, the plurality of device parameters that satisfy both a first condition and a second condition. The first condition is a condition that the comfort parameter be a value greater than a threshold value. The second condition is a condition that the air conditioning energy parameter be minimized within a range of the plurality of device parameters that satisfy the first condition. The result outputter (28) outputs the plurality of device parameters obtained by the selector (27).

This configuration enables selecting (a plurality of device parameters concerning) an arrangement condition and an operating condition that ensure both comfortableness based on the predicted mean vote and energy saving alike.

Note that these are not the only aspects of the present disclosure but various configurations (including variations) of the design system (1) according to the exemplary embodiment described above may also be implemented as, for example, a design method, a (computer) program, or a non-transitory storage medium on which the program is stored.

### REFERENCE SIGNS LIST

1 Design System
21 Acquirer
22 Sampler
23 Simulator
24 First Calculator
25 Second Calculator
26 Third Calculator
27 Selector
28 Result Outputter

1. A design method for designing a plurality of device parameters concerning an arrangement condition and an operating condition for air conditioning equipment, the design method comprising:
an acquisition step including acquiring information about respective settable ranges of the plurality of device parameters, the plurality of device parameters including an air volume, an outlet temperature, an installation position, and an air direction of the air conditioning equipment;
a sampling step including determining multiple samples, each of the multiple samples being a set of the plurality of device parameters falling within the settable ranges; and
a set calculating step including calculating multiple sets by performing a simulation step, a first calculating step, a second calculating step, and a third calculating step on every one of the multiple samples, each of the multiple sets including an air conditioning energy parameter and a comfort parameter,
the simulation step including carrying out a simulation of a thermal fluid distribution in a space of interest by using one sample, selected from the multiple samples, as an input condition, the space of interest forming at least part of a space to be air-conditioned by the air conditioning equipment
the first calculating step including calculating the air conditioning energy parameter with respect to the one sample by multiplying an absolute value of a difference between a target temperature of the space of interest and the outlet temperature by the air volume,
the second calculating step including calculating, based on a result of the simulation, a distribution of a predicted mean vote in the space of interest,
the third calculating step including calculating the comfort parameter by dividing a volume of a part of the space of interest where the predicted mean vote has a value falling within a predetermined range by an entire volume of the space of interest,
the design method further comprising a selecting step including obtaining, based on the multiple sets, each including the air conditioning energy parameter and the comfort parameter, which have been obtained with respect to the multiple samples, respectively, the plurality of device parameters that satisfy both a first condition and a second condition,
the first condition being a condition that the comfort parameter be a value greater than a threshold value, and
the second condition being a condition that the air conditioning energy parameter be minimized within a range of the plurality of device parameters that satisfy the first condition.

2. The design method of claim 1, wherein
the sampling step includes determining the multiple samples by design of experiments.

3. The design method of claim 1, wherein
the predetermined range is equal to or greater than −0.5 and equal to or less than 0.5.

4. The design method of claim 1, wherein
the threshold value is a value equal to or greater than 0.9 and equal to or less than 1.0.

5. The design method of claim 1, wherein
the selecting step includes:
generating interpolated data by interpolating data between the multiple samples; and
obtaining, based on the interpolated data, the plurality of device parameters that satisfy both the first condition and the second condition.

6. A non-transitory storage medium storing a program which is designed to cause one or more processors of a computer system to perform the design method of claim 1.

7. A design system configured to design a plurality of device parameters concerning an arrangement condition and an operating condition for air conditioning equipment, the design system comprising:
an acquirer configured to acquire information about respective settable ranges of the plurality of device parameters, the plurality of device parameters including an air volume, an outlet temperature, an installation position, and an air direction of the air conditioning equipment;
a sampler configured to determine multiple samples, each of the multiple samples being a set of the plurality of device parameters falling within the settable ranges;
a simulator configured to perform a simulation step, the simulation step including carrying out a simulation of a thermal fluid distribution in a space of interest by using one sample, selected from the multiple samples, as an input condition, the space of interest forming at least part of a space to be air-conditioned by the air conditioning equipment;
a first calculator configured to perform a first calculating step, the first calculating step including calculating the air conditioning energy parameter with respect to the one sample by multiplying an absolute value of a difference between a target temperature of the space of interest and the outlet temperature by the air volume;
a second calculator configured to perform a second calculating step, the second calculating step including calculating, based on a result of the simulation, a distribution of a predicted mean vote in the space of interest; and
a third calculator configured to perform a third calculating step, the third calculating step including calculating the comfort parameter by dividing a volume of a part of the space of interest where the predicted mean vote has a value falling within a predetermined range by an entire volume of the space of interest,
the simulator, the first calculator, the second calculator, and the third calculator respectively performing the simulation step, the first calculating step, the second calculating step, and the third calculating step on every one of the multiple samples, thereby calculating multiple sets, each of the multiple sets including the air conditioning energy parameter and the comfort parameter,
the design system further comprising:
a selector configured to obtain, based on the multiple sets, each including the air conditioning energy parameter and the comfort parameter, which have been obtained with respect to the multiple samples, respectively, the plurality of device parameters that satisfy both a first condition and a second condition; and
a result outputter configured to output the plurality of device parameters obtained by the selector,
the first condition being a condition that the comfort parameter be a value greater than a threshold value, and
the second condition being a condition that the air conditioning energy parameter be minimized within a range of the plurality of device parameters that satisfy the first condition.
